(19) United States
(12) Patent Application Publication
(10) Pub. No.: US 2026/0096335 A1
(43) Pub. Date: Apr. 2, 2026

(54) DISPLAY PANEL AND DISPLAY APPARATUS

(71) Applicant: Everdisplay Optronics (Shanghai) Co., Ltd., Shanghai (CN)

(72) Inventors: Haiyan HAO, Shanghai (CN); Chunmei WANG, Shanghai (CN); Ting CHEN, Shanghai (CN)

(73) Assignee: Everdisplay Optronics (Shanghai) Co., Ltd., Shanghai (CN)

(21) Appl. No.: 19/304,636

(22) Filed: Aug. 20, 2025

(30) Foreign Application Priority Data
Sep. 29, 2024 (CN) 2024113785973

(51) Int. Cl. H10K 59/80; H10K 59/122; H10K 59/40

(52) U.S. Cl. CPC H10K 59/879; H10K 59/122; H10K 59/40; H10K 59/873

(57) ABSTRACT

The present disclosure provides a display panel and a display apparatus, the display panel includes: a light-emitting element, a plurality of the light-emitting elements being arranged in an array; a pixel definition layer including a plurality of pixel definition holes arranged in an array, the light-emitting elements being located in the pixel definition holes; an encapsulation layer located on a side of the pixel definition layer and including a first inorganic layer, a light refraction layer and a second inorganic layer in a direction away from the pixel definition layer, the light refraction layer including a plurality of refraction components arranged in an array and a planarization layer, and at least part of light emitted from the light-emitting element being reflected by the refraction component and then emitted from a light-emitting surface of the display panel.

### CROSS REFERENCE

This application is based upon and claims priority to Chinese Patent Application No. 2024113785973, filed on Sep. 29, 2024, the entire contents thereof are incorporated herein by reference.

### TECHNICAL FIELD

The present disclosure relates to the field of display panels, and more specifically, to a display panel and a display apparatus.

### BACKGROUND

At present, the encapsulation technology of OLED display panels is mainly thin film encapsulation (TFE), which is usually a composite structure composed of organic and inorganic multilayer thin films. However, due to the refraction of the multilayer inorganic layers of the thin film encapsulation structure, part of the light cannot be transmitted, thereby reducing the light-emitting efficiency of the display panel.

It should be noted that the information disclosed in the above-mentioned background is only used to enhance the understanding of the background of the present disclosure, and therefore may include information that does not constitute the prior art known to those skilled in the art.

### SUMMARY

The present disclosure provides a display panel and a display apparatus.

On one hand, embodiments of the present disclosure provide a display panel, including:
a light-emitting element, where a plurality of light-emitting elements are arranged in an array;
a pixel definition layer, where the pixel definition layer includes a plurality of pixel definition holes arranged in an array, and the light-emitting elements are located in the pixel definition holes;
an encapsulation layer, where the encapsulation layer is located on a side of the pixel definition layer, and the encapsulation layer includes a first inorganic layer, a light refraction layer and a second inorganic layer in a direction away from the pixel definition layer, the light refraction layer has a plurality of refraction components arranged in an array and a planarization layer, and at least part of light emitted from the light-emitting element is reflected by the refraction component and then emitted from a light-emitting surface of the display panel.

On the other hand, the embodiments of the present disclosure also provide a display apparatus, including the above-mentioned display panel.

### BRIEF DESCRIPTION OF THE DRAWINGS

The accompanying drawings, which are incorporated in and constitute a part of this specification, illustrate embodiments consistent with the present disclosure and, together with the specification, serve to explain the principles of the present disclosure. Obviously, the drawings in the following description are only some embodiments of the present disclosure, and for those of ordinary skill in the art, other drawings can also be obtained according to these drawings without creative work.

FIG. 1 is a structural schematic diagram of a display panel in the related art;

FIG. 2 is a structural schematic diagram of a display panel provided by an embodiment of the present disclosure;

FIG. 3 is a structural schematic diagram of a display apparatus provided by an embodiment of the present disclosure.

Reference signs:

| | |
|---|---|
| 10 | Display panel |
| 11 | Light-emitting element |
| 12 | Pixel definition layer |
| 121 | Pixel definition hole |
| 13 | Encapsulation layer |
| 131 | First inorganic layer |
| 132 | Light refraction layer |
| 133 | Second inorganic layer |
| 134 | Refraction component |
| 135 | Planarization layer |
| 136 | Facet |
| 14 | Touch layer |
| 15 | Inkjet printing layer |
| 20 | Display apparatus |

### DETAILED DESCRIPTION

The example embodiments will now be described more fully with reference to the accompanying drawings. However, the example embodiments can be implemented in a variety of forms and should not be construed as being limited to the embodiments described herein. Instead, these embodiments are provided so that the present disclosure will be comprehensive and complete and the concept of the example embodiments will be fully conveyed to those skilled in the art. The same reference signs in the figures represent the same or similar structures, and thus their repeated description will be omitted.

The words “first”, “second” and similar words used in the specific description do not indicate any order, quantity or importance, but are only used to distinguish different components. In addition, in the description of the present disclosure, the orientation or position relationship indicated by the terms “upper”, “lower” and the like is based on the orientation or position relationship shown in the accompanying drawings, which is only for the convenience of description, rather than indicating or implying that the apparatus or element referred to must have a specific orientation, be constructed and operated in a specific orientation, and therefore cannot be understood as a limitation on the present disclosure.

It should be noted that, in the absence of conflict, the embodiments and the features in different embodiments of the present disclosure can be combined with each other.

In order to improve the light-emitting efficiency, a micro prism structure (Micro Lens Array, MLA) may be prepared on the thin film encapsulation layer of the OLED display panel to aggregate light and improve the luminous efficiency of the display panel. However, the combination of the thin film encapsulation layer and the micro prism structure in the OLED display panel significantly increases the overall thickness. In addition, the combination of the above-mentioned thin film encapsulation layer and the micro prism structure also causes the OLED display panel to have severe brightness attenuation and color deviation at large angles.

In view of this, the present disclosure provides a display panel and a display apparatus to at least solve the problems of large thickness of the display panel, and severe brightness attenuation and color deviation at large-angle in the related art.

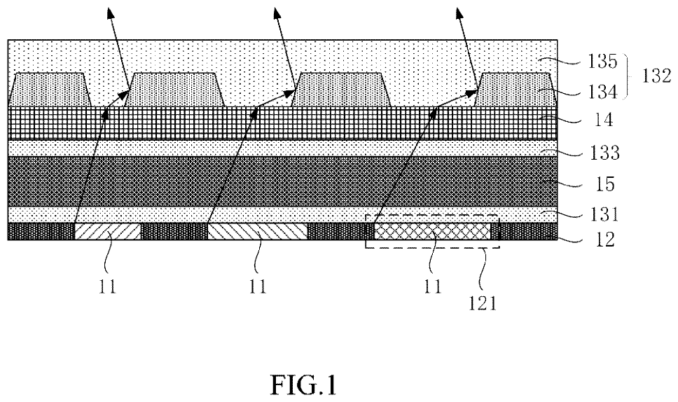

As shown in FIG. 1, in the related art, the display panel includes a pixel definition layer 12, a thin film encapsulation layer, a touch layer 14 and a light refraction layer 132 in sequence along its own light-emitting direction. The light-emitting element 11 is located in the pixel definition hole 121 of the pixel definition layer.

Specifically, along the light-emitting direction of the display panel, the thin film encapsulation layer includes a first inorganic layer 131, an inkjet printing layer 15 and a second inorganic layer 133 in sequence. The first inorganic layer 131 and the second inorganic layer 133 adopt inorganic materials to block water and oxygen, and the inkjet printing layer 15 adopt soft organic materials for easy folding and has a planarization effect. However, in the related art, due to the refraction of the multilayer inorganic layers of the thin film encapsulation structure, part of the light cannot be transmitted, thereby reducing the light-emitting efficiency of the display panel.

Specifically, the light refraction layer 132 includes a refraction component 134 and a planarization layer 135. The refraction component 134 in the light refraction layer 132 is a prism structure, and the light refraction layer 132 aggregates light through the prism refraction principle to improve the luminous efficiency of the display panel.

However, in the related art, due to the combination of the thin film encapsulation layer and the light refraction layer 132 in the display panel, the overall thickness increases significantly. In particular, as the thickness of the refraction component 134 in the light refraction layer 132 increases, the light aggregation efficiency can be significantly increased. In addition, due to the light aggregation effect of the light refraction layer 132, the light emitted by the light-emitting element 11 is mainly emitted in a direction roughly perpendicular to the plane where the display panel is located, which leads to serious brightness attenuation and color deviation of the display panel at large-angle.

The inventor of the present application has provided a solution to the problems existing in the related art through careful and in-depth research. The present disclosure provides a display panel and a display apparatus. The display panel includes: a light-emitting element, where a plurality of the light-emitting elements are arranged in an array; a pixel definition layer, where the pixel definition layer includes a plurality of pixel definition holes arranged in an array, and the light-emitting elements are located in the pixel definition holes; an encapsulation layer, where the encapsulation layer is located on a side of the pixel definition layer, and the encapsulation layer includes a first inorganic layer, a light refraction layer and a second inorganic layer in sequence along a direction away from the pixel definition layer, the light refraction layer has a plurality of refraction components arranged in an array and a planarization layer, and at least part of light emitted from the light-emitting element is reflected by the refraction component and then emitted from a light-emitting surface of the display panel. The display panel and the display apparatus of the present disclosure can significantly reduce the thickness of the display panel by using a light refraction layer of a microprism structure to replace the inkjet printing layer in the related art and eliminating the inkjet printing layer; at the same time, compared with the related art, the light refraction layer is closer to the light-emitting element, so that the angle between the light emitted by the light-emitting element to the refraction component and the plane of the refraction component that reflects the light increases, so that the angle between the light reflected by the refraction component and the plane of the display panel decreases, thereby increasing the brightness of the display panel at a wide viewing angle and improving the color deviation of the display panel at a wide viewing angle.

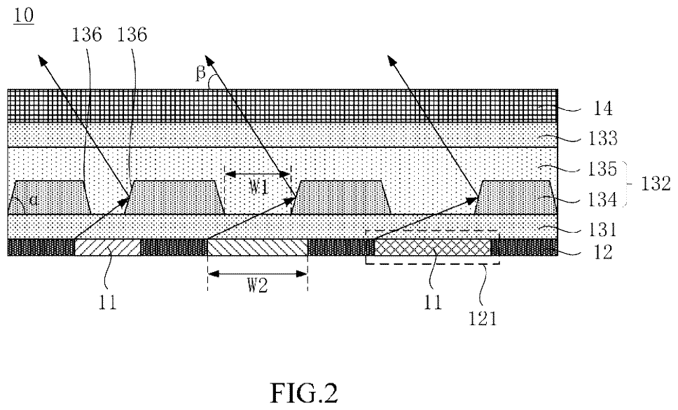

As shown in FIG. 2, on the one hand, an embodiment of the present disclosure provides a display panel 10, including a pixel definition layer 12, an encapsulation layer 13 and a touch layer 14.

Specifically, the display panel 10 includes a plurality of light-emitting elements 11, and the plurality of light-emitting elements 11 are arranged in an array. The light emitted from the light-emitting element 11 passes through the encapsulation layer 13 and the touch layer 14 in sequence, and then is emitted from the light-emitting surface of the display panel 10.

Specifically, the pixel definition layer 12 includes a plurality of pixel definition holes 121 arranged in an array, the pixel definition holes 121 correspond to the light-emitting elements 11 one by one, and the light-emitting elements 11 are located in the pixel definition holes 121.

Specifically, the encapsulation layer 13 is located on the side of the pixel definition layer 12 close to the light-emitting direction of the display panel 10. The encapsulation layer 13 includes a first inorganic layer 131, a light refraction layer 132, and a second inorganic layer 133 in sequence along the direction away from the pixel definition layer 12, and is used to encapsulate the display panel 10 to form an effective composite structure for blocking water and oxygen. By using the light refraction layer 132 to replace the inkjet printing layer 15 in the thin film encapsulation layer in the related art, and canceling the inkjet printing layer 15, a new encapsulation layer 13 is formed, therefore the thickness of the display panel 10 can be significantly reduced. In addition, since the inkjet printing layer 15 is canceled, the preparation materials of the display panel 10 are reduced, and the preparation difficulty and preparation cost can also be reduced.

Further, the light refraction layer 132 has a plurality of refraction components 134 arranged in an array and a planarization layer 135. A light-emitting region is formed between every two adjacent refraction components 134, each light-emitting region corresponds to one light-emitting element 11, and the light emitted by the light-emitting element 11 is emitted from the light-emitting region. The edges of each light-emitting region are the reflection surfaces of two refraction components 134. In the light emitted from the light-emitting element 11, part of the light with a relatively small angle with the direction perpendicular to the plane where the display panel 10 is located is directly emitted from the light-emitting region. Part of the light with a relatively large angle with the direction perpendicular to the plane where the display panel 10 is located is reflected by the refraction component 134 and emitted from the light-emitting surface of the display panel 10. In the above arrangement, compared with the related art, the light refraction layer 132 is closer to the light-emitting element 11, so that the angle between the light emitted by the light-emitting element 11 to the refraction component 134 and the plane of the refraction component 134 that reflects the light increases, so that the angle between the light reflected by the refraction component 134 and the plane of the display panel 10 is reduced, thereby increasing the brightness of the display panel 10 at a large viewing angle and improving the color deviation of the display panel 10 at a large viewing angle.

Furthermore, the light refraction layer 132 may be a micro prism structure (Micro Lens Array, MLA), that is, an integrated micro prism technology is used. The light refraction layer 132 may change the transmission path of the light emitted from the light-emitting element 11 by adding a refraction component 134 of a prism structure above each light-emitting element 11, and by introducing a high refractive index and high transmittance material, so that the originally divergent light can be focused in a substantially vertical direction of the display panel 10, thereby improving the front light-emitting efficiency of the display panel 10. Specifically, the material of the refraction component 134 may be zirconium dioxide (ZrO2).

Continuing to refer to FIG. 2, in some embodiments, the refraction component 134 may be a prism structure. The facet 136 of the refraction component 134 for reflecting the light emitted from the light-emitting element 11 forms a first angle α with the plane where the display panel 10 is located, and the range of the first angle α is 65° to 80°. Specifically, the degree of the first angle α may be at least any value of 65°, 68°, 71°, 74°, 77° or 80°, which is not limited by the present application. It should be noted that two adjacent refraction components 134 have two slopes opposite to each other, and the slopes are the facets 136 for reflecting the light emitted from the light-emitting element 11. Along the light-emitting direction of the display panel 10, the two facets 136 are inclined in a direction away from each other. Further, in order to make the light emitted from the light-emitting element 11 be emitted from the display panel 10 as much as possible, so as to increase the brightness of the display panel 10 at a wide viewing angle and improve the color deviation of the display panel 10 at a wide viewing angle, this can be achieved by adjusting the range of the first angle α formed by the facet 136 of the refraction component 134 and the plane where the display panel 10 is located. Specifically, the larger the first angle α, the larger the angle formed by the light emitted from the light-emitting element 11 to the refraction component 134 and the plane of the refraction component 134 that reflects the light, so that the angle formed by the light reflected by the refraction component 134 and the plane of the display panel 10 is smaller, thereby increasing the brightness of the display panel 10 at a wide viewing angle and improving the color deviation of the display panel 10 at a wide viewing angle.

Continuing to refer to FIG. 2, in some embodiments, the refraction component 134 is located on the side of the planarization layer 135 close to the first inorganic layer 131, and the facets 136 and the upper surface of the refraction component 134 are in surface contact with the planarization layer 135, and the lower surface of the refraction component 134 is in surface contact with the first inorganic layer 131. In the related art, the upper surfaces of the pixel definition layer 12 and the light-emitting element 11 are uneven due to that the pixel definition holes 121 of the pixel definition layer 12 accommodates the light-emitting elements 11, and the first inorganic layer 131 is prepared on the pixel definition layer 12 and the light-emitting elements 11, and thus also presents unevenness. In the related art, an inkjet printing layer 15 is used to planarize it. In addition, since the refraction component 134 is a microprism structure, its upper surface is uneven. In the related art, a planarization layer 135 is used to planarize it. However, the above two planarization structures lead to an increase in the thickness of the display panel. The above-mentioned setting of the present application, by using one planarization structure, that is, the planarization layer 135, can simultaneously solve the unevenness caused by the pixel definition layer 12 and the refraction component 134, so that the upper surfaces of the pixel definition layer 12 and the refraction component 134 are flat, which is convenient for preparing the second inorganic layer 133 and subsequent film layer(s), and significantly reduces the thickness of the display panel 10.

In some embodiments, along the direction perpendicular to the plane where the display panel 10 is located, the total thickness of the light refraction layer 132 is 7 μm˜12.5 μm, where the thickness of the refraction component 134 is 1.0 μm˜2.5 μm, and the thickness of the thinnest part of the planarization layer 135 is 6 μm˜10 μm. Specifically, the thickness of the refraction component 134 can be at least any value of 1.0 μm, 1.5 μm, 2.0 μm or 2.5 μm, which is not limited by the present application. The thickness of the thinnest part of the planarization layer 135 can be at least any value of 6 μm, 7 μm, 8 μm, 9 μm or 10 μm, which is not limited by the present application. The above-mentioned thickness setting of the refraction component 134 and the planarization layer 135 can reduce the total thickness of the display panel 10. At the same time, the refraction component 134 of the light refraction layer 132 is closer to the light-emitting element 11, thereby increasing the brightness of the display panel 10 at a wide viewing angle and improving the color deviation of the display panel 10 at a wide viewing angle.

Continuing to refer to FIG. 2, in some embodiments, after being refracted by the refraction component 134, the light emitted from the light-emitting surface of the display panel 10 forms a second angle β with the plane where the display panel 10 is located, and the range of the second angle β is 10° ˜90°. Specifically, the degree of the second angle β can be at least any value of 10°, 20°, 30°, 40°, 50°, 60°, 70°, 80° or 90°, which is not limited by the present application. The above angle range of the second angle β can increase the brightness of the display panel 10 at a wide viewing angle and improve the color deviation of the display panel 10 at a wide viewing angle.

In some embodiments, the refractive index of the refraction component 134 is less than that of the planarization layer 135 to change the transmission path of the light emitted from the light-emitting element 11, so that the light emitted from the light-emitting element 11 is emitted from the light-emitting surface of the display panel 10 as much as possible, thereby improving the light-emitting efficiency of the display panel 10. The refractive index of the refraction component 134 is 1.40˜1.50, and the refractive index of the planarization layer 135 is 1.60˜1.80. The above values of the refractive index of the refraction component 134 and the planarization layer 135 can be matched with the distance between the refraction component 134 and the light-emitting element 11, so that the light emitted from the light-emitting element 11, after reflection by the refraction component 134, finally forms a second angle β with the plane where the display panel 10 is located in the range of 10° ˜90°, so as to increase the brightness of the display panel 10 at a wide viewing angle and improve the color deviation of the display panel 10 at a wide viewing angle.

Continuing to refer to FIG. 2, in some embodiments, the display panel 10 also includes: a touch layer 14. The touch layer 14 is located on the side of the second inorganic layer 133 away from the first inorganic layer 131. The touch layer 14 is used to provide a touch structure for the display panel 10 so that the display panel 10 can provide a touch operation. The above-mentioned setting, in which the light refraction layer 132 with a microprism structure is arranged between the touch layer 14 and the pixel definition layer 12, can significantly reduce the thickness of the display panel 10. At the same time, the light refraction layer 132 can be closer to the light-emitting element 11, thereby increasing the brightness of the display panel 10 at a wide viewing angle and improving the color deviation of the display panel 10 at a wide viewing angle. The touch layer 14 can be self-capacitive or mutual-capacitive, which is not limited by the present application. The self-capacitive touch layer 14 is usually a capacitive sensor layer, which is made of a transparent conductive material (such as indium tin oxide, ITO) to form a plurality of capacitive sensor units. The mutual-capacitive touch layer 14 is composed of a horizontal layer and a vertical layer of capacitive sensors to form a grid structure. These two layers are also made of transparent conductive materials.

In some embodiments, along the direction perpendicular to the plane where the display panel 10 is located, the thickness of the first inorganic layer 131 is 1.2 μm˜1.5 μm, and the thickness of the second inorganic layer 133 is 0.6 μm˜1.0 μm. Specifically, the thickness of the first inorganic layer 131 can be at least any value of 1.2 μm, 1.3 μm, 1.4 μm or 1.5 μm, which is not limited in the present application. The thickness of the second inorganic layer 133 can be at least any value of 0.6 μm, 0.7 μm, 0.8 μm, 0.9 μm or 1.0 μm, which is not limited in the present application. The above-mentioned thickness setting of the first inorganic layer 131 and the second inorganic layer 133 can reduce the total thickness of the display panel 10. At the same time, the refraction component 134 of the light refraction layer 132 is closer to the light-emitting element 11, thereby increasing the brightness of the display panel 10 at a wide viewing angle and improving the color deviation of the display panel 10 at a wide viewing angle.

Furthermore, the first inorganic layer 131 and the second inorganic layer 133 may be made of silicon nitride or silicon oxide materials to effectively prevent water and oxygen from corroding the light-emitting element 11. The planarization layer 135 may be made of organic materials, which is easy to fold and has a planarization effect.

In some embodiments, the refractive indexes of the first inorganic layer 131, the planarization layer 135 and the second inorganic layer 133 may decrease in sequence. It should be noted that the refractive index of the first inorganic layer 131 is greater than the refractive index of the planarization layer 135, which can increase the angle between the light emitted by the light-emitting element 11 to the refraction component 134 and the plane of the refraction component 134 that reflects the light, thereby reducing the second angle β between the light reflected by the refraction component 134 and the plane of the display panel 10, thereby increasing the brightness of the display panel 10 at a wide viewing angle and improving the color deviation of the display panel 10 at a wide viewing angle. The refractive index of the planarization layer 135 is greater than the refractive index of the second inorganic layer 133, which can reduce the second angle β between the light reflected by the refraction component 134 and the plane of the display panel 10, thereby increasing the brightness of the display panel 10 at a wide viewing angle and improving the color deviation of the display panel 10 at a wide viewing angle.

In some embodiments, for each light-emitting element 11, a light-emitting region is formed between adjacent refraction components 134 corresponding to the light-emitting element 11, and the area of the light-emitting region is smaller than the light-emitting area of the light-emitting element 11. It is understandable that for the light-emitting elements 11 of different colors, their light-emitting areas may be different, and the areas of the light-emitting regions formed between the corresponding refraction components 134 may also be different. However, for each light-emitting element 11, its light-emitting area and the light-emitting region formed between the corresponding refraction components 134 satisfy the above relationship. The above setting can make the light emitted from the light-emitting element 11 directly pass through the light-emitting region between the refraction components 134 or pass through the light-emitting region after being reflected by the refraction components 134 as much as possible, so that the light emitted from the light-emitting element 11 can be emitted from the display panel 10 as much as possible, which improves the overall light-emitting efficiency of the display panel 10, and reduces the interface emission of the display panel 10.

Continuing to refer to FIG. 2, in some embodiments, along the direction parallel to the plane where the display panel 10 is located, the distance between two adjacent refraction components 134 is less than or equal to the light-emitting width of the light-emitting element 11. Specifically, the distance between two adjacent refraction components 134 is W1, and the light-emitting width of the light-emitting element 11 is W2, W1≤W2. It can be understood that for the light-emitting elements 11 of different colors, the values of their light-emitting width W2 can be different, and the distance W1 between the two corresponding refraction components 134 can also be different. However, for each light-emitting element 11, W1 and W2 both satisfy W1≤W2. It should be noted that W1 and W2 satisfy the above relationship, so that the light emitted from the light-emitting element 11 can directly pass through the light-emitting region between the refraction components 134 or pass through the light-emitting region after being reflected by the refraction components 134 as much as possible, so that the light emitted from the light-emitting element 11 can be emitted from the display panel 10 as much as possible, thereby improving the overall light-emitting efficiency of the display panel 10 and reducing the interface emission of the display panel 10.

Continuing to refer to FIG. 2, in some embodiments, the projection of the light refraction layer 132 based on the plane where the display panel 10 is located is completely contained in the projections of the first inorganic layer 131 and the second inorganic layer 133 based on the plane where the display panel 10 is located, respectively. In the above-mentioned setting, the light refraction layer 132 is completely included in the first inorganic layer 131 and the second inorganic layer 133, so that the light refraction layer 132, the first inorganic layer 131 and the second inorganic layer 133 together form a water and oxygen blocking structure, thereby effectively preventing water and oxygen from corroding the light-emitting element 11. At the same time, the light emitted from the light-emitting element 11 can pass through the first inorganic layer 131 and the second inorganic layer 133, ensuring the uniformity of display at different positions of the display panel 10.

The display panel 10 of the present disclosure can significantly reduce the thickness of the display panel 10 by using the light refraction layer 132 of the microprism structure to replace the inkjet printing layer 15 in the related art, and canceling the inkjet printing layer 15; at the same time, compared with the related art, the light refraction layer 132 is closer to the light-emitting element 11, so that the angle between the light emitted by the light-emitting element 11 to the refraction component 134 and the plane of the refraction component 134 for reflecting the light increases, so that the angle between the light reflected by the refraction component 134 and the plane of the display panel 10 decreases, thereby increasing the brightness of the display panel 10 at a wide viewing angle and improving the color deviation of the display panel 10 at a wide viewing angle.

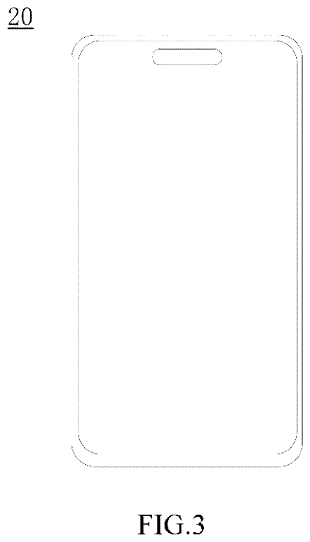

As shown in FIG. 3, on the other hand, an embodiment of the present disclosure further provides a display apparatus 20, including the above-mentioned display panel 10 provided by the embodiments of the present disclosure. The display apparatus 20 may be any product or component with display function, such as a mobile phone, a tablet computer, a television, a display, a laptop computer, a digital photo frame, a navigator, etc. The specific implementation and technical effects of the display apparatus 20 can refer to the specific embodiments of the display panel 10 and its preparation method, and the repetitive parts will not be repeated.

In summary, the display panel and the display apparatus of the present disclosure can significantly reduce the thickness of the display panel by using the light refraction layer with a microprism structure to replace the inkjet printing layer in the related art and canceling the inkjet printing layer; at the same time, compared with the related art, the light refraction layer is closer to the light-emitting element, so that the angle between the light emitted by the light-emitting element to the refraction component and the plane of the refraction component that reflects the light increases, so that the angle between the light reflected by the refraction component and the plane of the display panel decreases, thereby increasing the brightness of the display panel at a wide viewing angle and improving the color deviation of the display panel at a wide viewing angle.

The above content is a further detailed description of the present disclosure in combination with specific optional implementations, and it cannot be determined that the specific implementation of the present disclosure is limited to these descriptions. For ordinary technicians in the technical field to which the present disclosure belongs, several simple deductions or substitutions can be made without departing from the concept of the present disclosure, which should be regarded as belonging to the protection scope of the present disclosure.

What is claimed is:

1. A display panel, comprising:
a light-emitting element, wherein a plurality of the light-emitting elements are arranged in an array;
a pixel definition layer, wherein the pixel definition layer comprises a plurality of pixel definition holes arranged in an array, and the light-emitting elements are located in the pixel definition holes; and
an encapsulation layer, wherein the encapsulation layer is located on one side of the pixel definition layer, the encapsulation layer comprises a first inorganic layer, a light refraction layer and a second inorganic layer in sequence along a direction away from the pixel definition layer, the light refraction layer comprises a plurality of refraction components arranged in an array and a planarization layer, and at least part of light emitted from the light-emitting element is reflected by the refraction component and then emitted from a light-emitting surface of the display panel.

2. The display panel according to claim 1, wherein the refraction component is a prism structure, a facet of the refraction component for reflecting the light emitted from the light-emitting element forms a first angle with a plane where the display panel is located, and the first angle ranges from 65° to 80°.

3. The display panel according to claim 2, wherein the refraction component is located on a side of the planarization layer close to the first inorganic layer, the facets and an upper surface of the refraction component are in surface contact with the planarization layer, and a lower surface of the refraction component is in surface contact with the first inorganic layer;
along a direction perpendicular to the plane where the display panel is located, a total thickness of the light refraction layer is 7 μm˜12.5 μm, wherein a thickness of the refraction component is 1.0 μm˜2.5 μm, and a thickness of a thinnest part of the planarization layer is 6 μm˜10 μm.

4. The display panel according to claim 1, wherein after being refracted by the refraction component, the light emitted from the light-emitting surface of the display panel forms a second angle with the plane where the display panel is located, and the second angle ranges from 10° to 90°.

5. The display panel according to claim 1, wherein a refractive index of the refraction component is less than that of the planarization layer; wherein the refractive index of the refraction component is 1.40˜1.50, and the refractive index of the planarization layer is 1.60˜1.80.

6. The display panel according to claim 1, further comprising:
a touch layer, wherein the touch layer is located on a side of the second inorganic layer away from the first inorganic layer, and the touch layer is self-capacitive or mutual-capacitive.

7. The display panel according to claim 1, wherein along a direction perpendicular to the plane where the display panel is located, a thickness of the first inorganic layer is 1.2 μm˜1.5 μm, and a thickness of the second inorganic layer is 0.6 μm˜1.0 μm.

8. The display panel according to claim 1, wherein for each of the light-emitting elements, a light-emitting region is formed between adjacent refraction components corresponding to the light-emitting element, and an area of the light-emitting region is smaller than a light-emitting area of the light-emitting element.

9. The display panel according to claim 1, wherein a projection of the light-refractive layer based on the plane where the display panel is located is completely contained in projections of the first inorganic layer and the second inorganic layer based on the plane where the display panel, respectively.

10. A display apparatus, comprising a display panel, wherein the display panel comprises:
a light-emitting element, wherein a plurality of the light-emitting elements are arranged in an array;
a pixel definition layer, wherein the pixel definition layer comprises a plurality of pixel definition holes arranged in an array, and the light-emitting elements are located in the pixel definition holes; and
an encapsulation layer, wherein the encapsulation layer is located on one side of the pixel definition layer, the encapsulation layer comprises a first inorganic layer, a light refraction layer and a second inorganic layer in sequence along a direction away from the pixel definition layer, the light refraction layer comprises a plurality of refraction components arranged in an array and a planarization layer, and at least part of light emitted from the light-emitting element is reflected by the refraction component and then emitted from a light-emitting surface of the display panel.

11. The display apparatus according to claim 10, wherein the refraction component is a prism structure, a facet of the refraction component for reflecting the light emitted from the light-emitting element forms a first angle with a plane where the display panel is located, and the first angle ranges from 65° to 80°.

12. The display apparatus according to claim 11, wherein the refraction component is located on a side of the planarization layer close to the first inorganic layer, the facets and an upper surface of the refraction component are in surface contact with the planarization layer, and a lower surface of the refraction component is in surface contact with the first inorganic layer;
along a direction perpendicular to the plane where the display panel is located, a total thickness of the light refraction layer is 7 μm˜12.5 μm, wherein a thickness of the refraction component is 1.0 μm˜2.5 μm, and a thickness of a thinnest part of the planarization layer is 6 μm˜10 μm.

13. The display apparatus according to claim 10, wherein after being refracted by the refraction component, the light emitted from the light-emitting surface of the display panel forms a second angle with the plane where the display panel is located, and the second angle ranges from 10° to 90°.

14. The display apparatus according to claim 10, wherein a refractive index of the refraction component is less than that of the planarization layer; wherein the refractive index of the refraction component is 1.40˜1.50, and the refractive index of the planarization layer is 1.60˜1.80.

15. The display apparatus according to claim 10, further comprising:
a touch layer, wherein the touch layer is located on a side of the second inorganic layer away from the first inorganic layer, and the touch layer is self-capacitive or mutual-capacitive.

16. The display apparatus according to claim 10, wherein along a direction perpendicular to the plane where the display panel is located, a thickness of the first inorganic layer is 1.2 μm˜1.5 μm, and a thickness of the second inorganic layer is 0.6 μm˜1.0 μm.

17. The display apparatus according to claim 10, wherein for each of the light-emitting elements, a light-emitting region is formed between adjacent refraction components corresponding to the light-emitting element, and an area of the light-emitting region is smaller than a light-emitting area of the light-emitting element.

18. The display apparatus according to claim 10, wherein a projection of the light-refractive layer based on the plane where the display panel is located is completely contained in projections of the first inorganic layer and the second inorganic layer based on the plane where the display panel, respectively.
